(19) United States
(12) Patent Application Publication
(10) Pub. No.: US 2013/0169606 A1
(43) Pub. Date: Jul. 4, 2013

(54) LIGHT DIRECTION DISTRIBUTION SENSOR

(71) Applicants: Ye Yin, Santa Clara, CA (US); Russell W. Gruhlke, Milpitas, CA (US)

(72) Inventors: Ye Yin, Santa Clara, CA (US); Russell W. Gruhlke, Milpitas, CA (US)

(73) Assignee: QUALCOMM MEMS TECHNOLOGIES, INC., San Diego, CA (US)

(21) Appl. No.: 13/341,094

(22) Filed: Dec. 30, 2011

(51) Int. Cl. G09G 5/00; H01L 27/148; B23P 17/04; G01J 1/42

(52) U.S. Cl. 345/207; 250/208.6; 29/428

(57) ABSTRACT

This disclosure provides systems, methods and apparatus for measuring the direction distribution of light. In some implementations, an ambient light direction distribution sensor device can include, for example, a light steering layer that is designed to steer light from different incident angles toward associated locations on a light detector. The light detector can then output one or more signals that are indicative of the amount of light that is incident upon the sensor device from different incident angles. These measurements can be used to control various parameters of a display in response to the detected ambient lighting conditions.

### TECHNICAL FIELD

This disclosure relates to measurement of the angular distribution of light. For example, this disclosure relates to measurement of the angular distribution of ambient light that is incident upon a surface of an optical display, including reflective optical displays with pixels made from electromechanical systems.

### DESCRIPTION OF THE RELATED TECHNOLOGY

Electromechanical systems (EMS) include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Interferometric modulators can be used, for example, as pixels in optical displays. Such interferometric modulator displays may be reflective in nature in that they may form a viewable picture by modulating and reflecting ambient light that is incident upon them. In an ambient light mode of operation, the angular distribution of ambient light that is incident upon the reflective display can influence various performance factors of the display, such as view angle, color, and/or brightness. The ambient light distribution can vary significantly in different viewing conditions. For example, the ambient light distribution may be Lambertian-like in an outdoor, cloudy viewing environment in which light is incident on the display from a wide range of directions (e.g., diffuse lighting conditions). Alternatively, the ambient light distribution may be relatively directed in an indoor viewing environment with, for example, a single light source, such as a lamp that is directed onto the display (e.g., directed lighting conditions).

### SUMMARY

The systems, methods and devices of the disclosure each have several innovative aspects, no single one of which is solely responsible for the desirable attributes disclosed herein.

One innovative aspect of the subject matter described in this disclosure can be implemented in a device for measuring angular distribution of light, the device including a light detector including a plurality of light detecting elements; a light steering layer including a plurality of light steering elements, each of the light steering elements being associated with a light detecting element and an incident direction, wherein each of the light steering elements is configured to steer incident light from its associated incident direction toward its associated light detecting element without substantially steering incident light from other incident directions toward its associated light detecting element, and wherein different light steering elements are associated with different incident directions and different light detecting elements to allow for measurement of the angular distribution of the incident light; and a plurality of light baffles between the plurality of light detecting elements and the plurality of light steering elements, wherein the plurality of light baffles are configured to reduce the amount of light that passes from the light steering elements to ones of the light detecting elements other than the respective light detecting elements to which the plurality of light steering elements are configured to steer light. This device may further include a processor communicatively coupled to the light detecting elements, the processor being configured to determine a measure of the amount of light incident upon the device from the plurality of different incident directions based on signals from the light detecting elements.

In another implementation, a device for measuring angular distribution of light includes means for detecting light; means for steering light associated with the light detecting means, wherein the light steering means are configured to steer incident light with different incident directions to different associated light detecting means to allow for measurement of the angular distribution of the incident light; and means for reducing crosstalk between the light detecting means and light steering means, wherein the crosstalk reduction means are configured to reduce the amount of light that passes from the light steering means to light detecting means other than the associated light detecting means to which the light steering means are configured to steer light.

In another implementation, a method of fabricating a device for measuring angular distribution of light includes providing a plurality of light detecting elements; providing a plurality of light steering elements above the plurality of light detecting elements, each of the light steering elements being associated with a light detecting element and an incident direction, wherein each of the light steering elements is configured to steer light from its associated incident direction toward its associated light detecting element without substantially steering incident light from other incident directions toward its associated light detecting element, wherein different light steering elements are associated with different incident directions and different light detecting elements to allow for measurement of the angular distribution of the incident light; and providing a plurality of light baffles between the light detecting elements and the light steering elements, wherein the plurality of light baffles are configured to reduce the amount of light that passes from the light steering elements to ones of the light detecting elements other than the respective light detecting elements to which the plurality of light steering elements are configured to steer light.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 is a cross-sectional schematic illustration of an example of a device for measuring the angular distribution of incident light.

FIG. 10 is a perspective view of the light direction distribution sensor device illustrated in FIG. 9.

FIG. 11 is a cross-sectional schematic illustration that shows how crosstalk may occur in light angular distribution measurements taken by some implementations of the device illustrated in FIG. 9.

FIG. 12 is a cross-sectional schematic illustration of an example device for measuring the angular distribution of incident light with reduced susceptibility to crosstalk.

FIG. 13 is a cross-sectional schematic illustration of another example device for measuring the angular distribution of incident light with reduced susceptibility to crosstalk.

FIG. 14A is a cross-sectional schematic illustration of yet another example device for measuring the angular distribution of incident light with reduced susceptibility to crosstalk.

FIG. 14B is a cross-sectional schematic illustration of another example device for measuring the angular distribution of incident light with reduced susceptibility to crosstalk.

FIG. 15 is a flowchart that illustrates an example method for fabricating a device for measuring the angular distribution of incident light.

FIGS. 16A and 16B show examples of system block diagrams illustrating an example display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

Various implementations of an ambient light direction distribution sensor device are described herein. The sensor device can include, for example, a light steering layer that is designed to steer light from different incident angles toward associated locations on a light detector. The light detector can then output one or more signals that are indicative of the amount of light that is incident upon the sensor device from different incident angles. The sensor device can also include light baffles to create, for example, optical channels between locations on the light steering layer and the associated locations on the light detector. The light baffles can reduce crosstalk amongst the output signals from the light detector by reducing the amount of light that arrives at a location on the light detector from non-associated incident angles. In some implementations, the light direction distribution sensor can be used to measure the angular distribution of light incident on a display. Particular implementations of the subject matter described in this disclosure can be implemented to realize one or more of the following potential advantages. As previously mentioned, the angular distribution of ambient light that is incident upon a reflective interferometric modulator display can influence various performance factors of the display, such as view angle, color, and/or brightness. Since the ambient light distribution can vary significantly in different viewing conditions (e.g., from Lambertian-like to directed), the implementations of a light direction distribution sensor device disclosed herein can advantageously be used to measure the ambient light direction distribution and to provide such measurements to a processor that adjusts various parameters of the display in response to the detected ambient lighting conditions. Some examples of the parameters of the display include artificial illumination levels (which may be associated with a particular voltage or current flow level), primary color light levels (e.g., red, green, blue light levels), and emitted view cone of light and/or desired light diffusion level.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

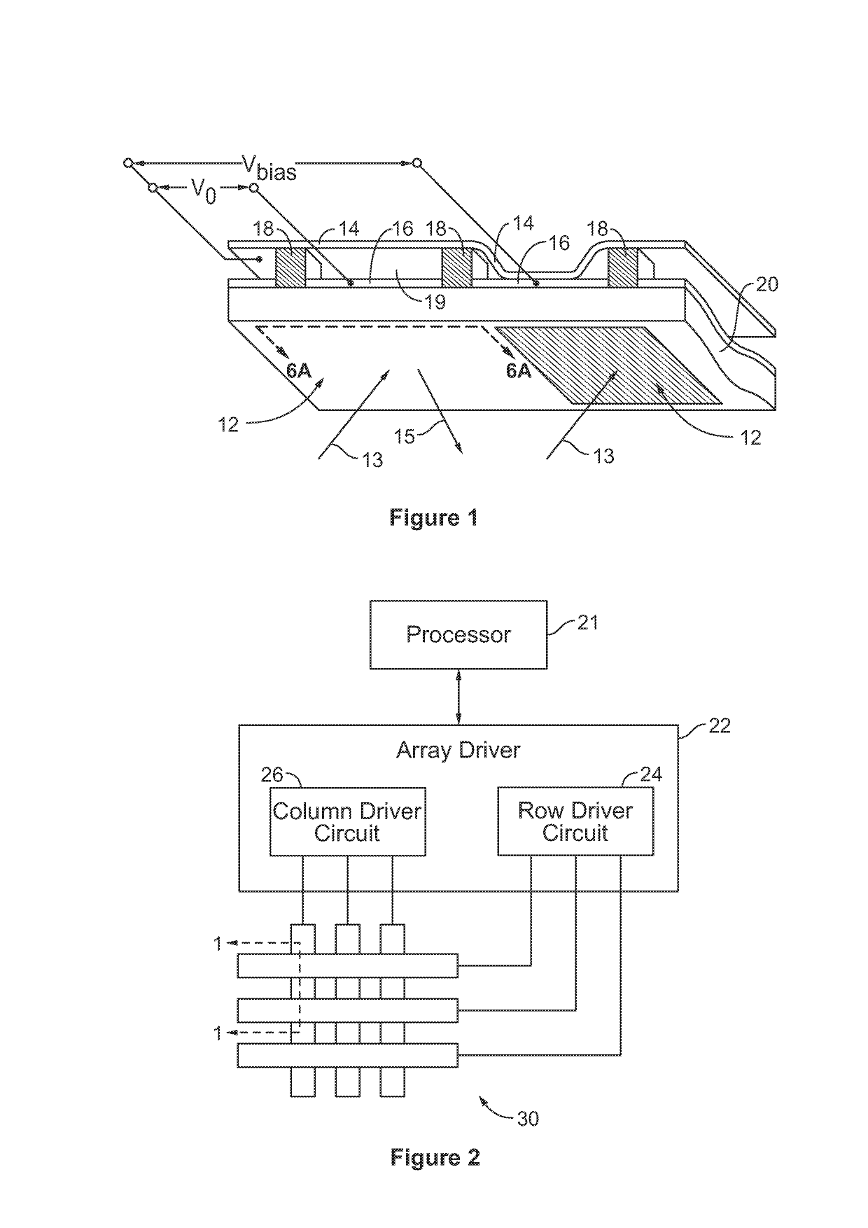

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V0 applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage Vbias applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than approximately 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

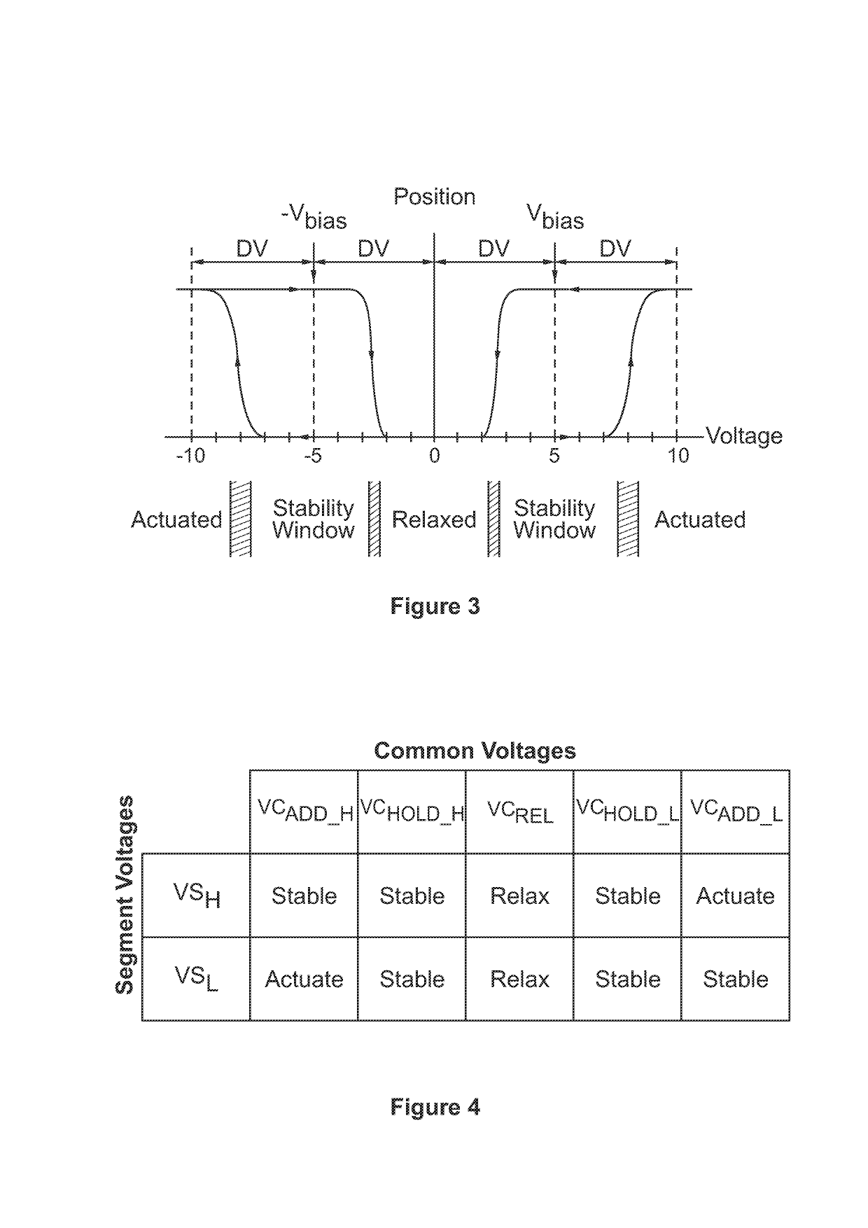

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

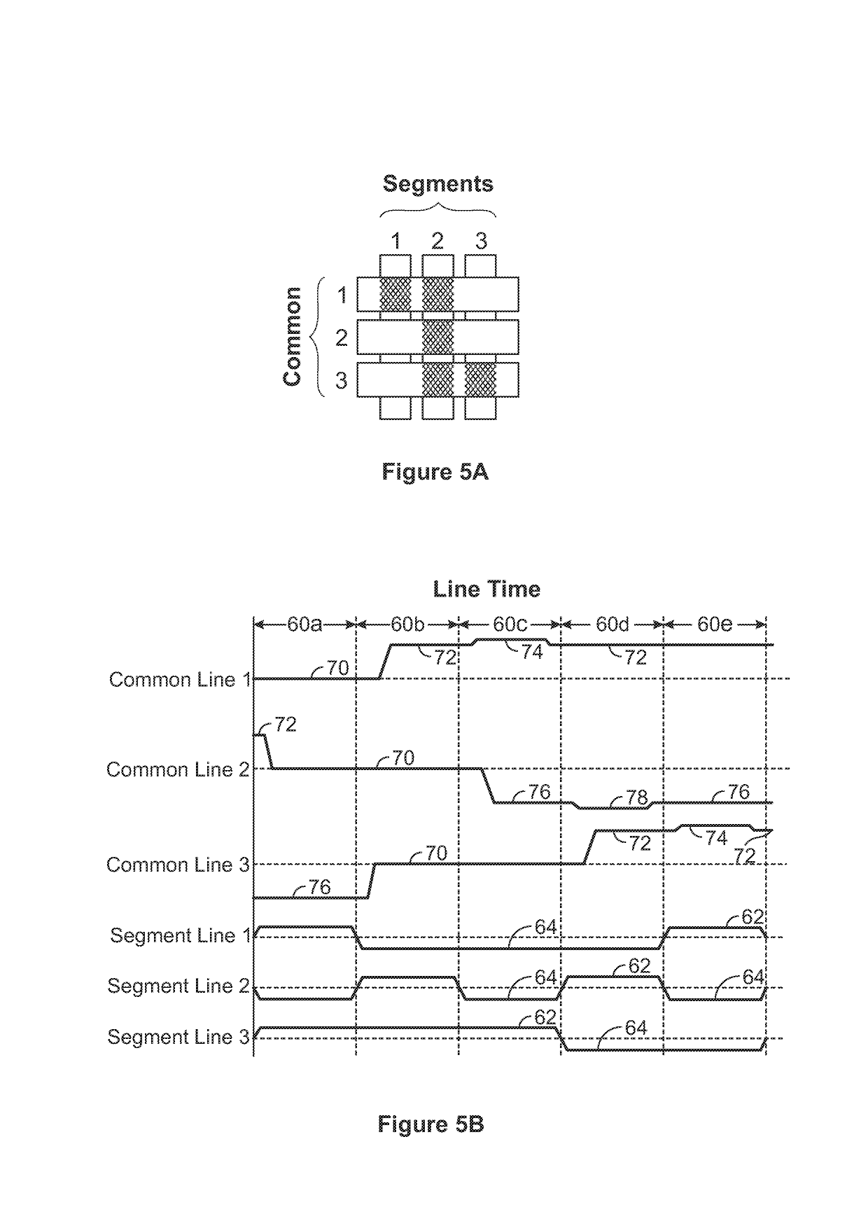

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

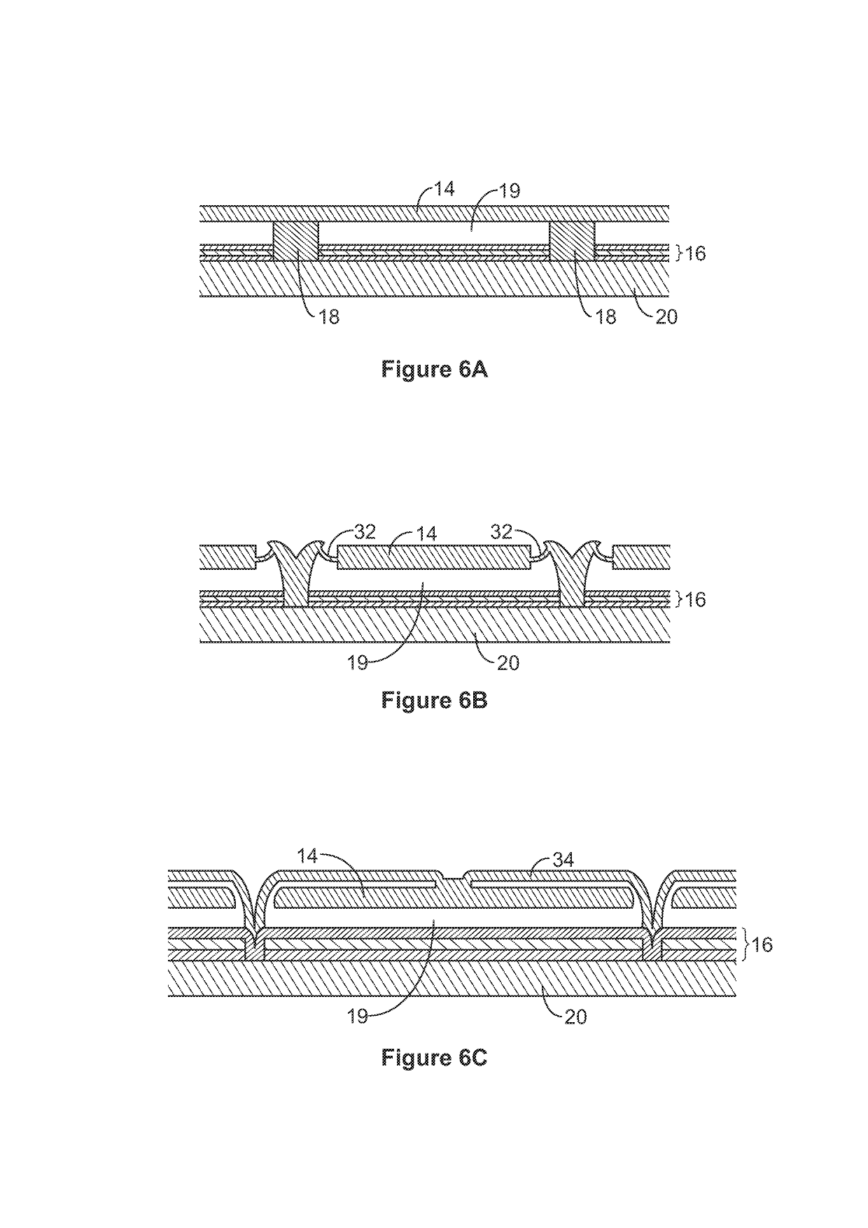

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

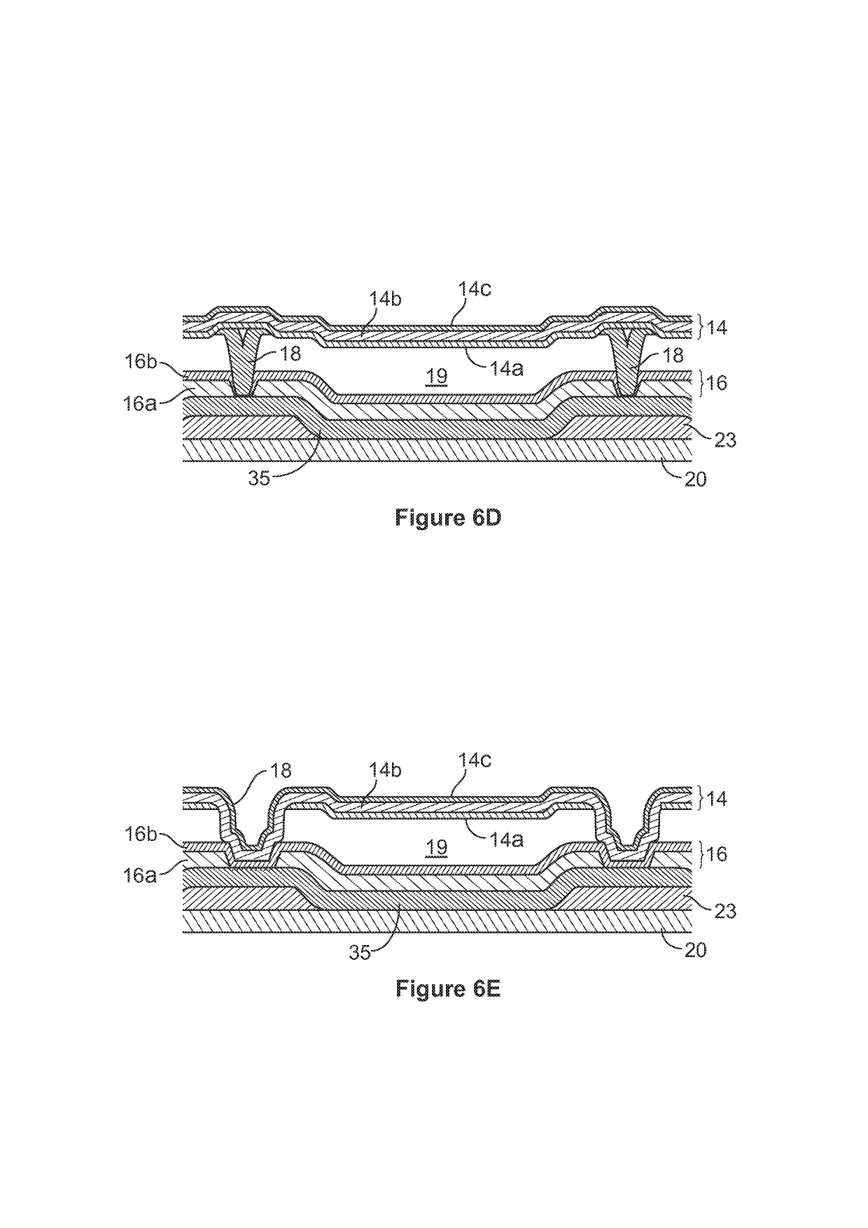

As illustrated in FIG. 4 (as well as in the timing diagram shown in FIG. 5B), when a release voltage VCREL is applied along a common line, all interferometric modulator elements along the common line will be placed in a relaxed state, alternatively referred to as a released or unactuated state, regardless of the voltage applied along the segment lines, i.e., high segment voltage VSH and low segment voltage VSL. In particular, when the release voltage VCREL is applied along a common line, the potential voltage across the modulator (alternatively referred to as a pixel voltage) is within the relaxation window (see FIG. 3, also referred to as a release window) both when the high segment voltage VSH and the low segment voltage VSL are applied along the corresponding segment line for that pixel.

When a hold voltage is applied on a common line, such as a high hold voltage VCHOLD_H or a low hold voltage VCHOLD_L, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VSH and the low segment voltage VSL are applied along the corresponding segment line. Thus, the segment voltage swing, i.e., the difference between the high VSH and low segment voltage VSL, is less than the width of either the positive or the negative stability window.

When an addressing, or actuation, voltage is applied on a common line, such as a high addressing voltage VCADD_H or a low addressing voltage VCADD_L, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VCADD_H is applied along the common line, application of the high segment voltage VSH can cause a modulator to remain in its current position, while application of the low segment voltage VSL can cause actuation of the modulator. As a corollary, the effect of the segment voltages can be the opposite when a low addressing voltage VCADD_L is applied, with high segment voltage VSH causing actuation of the modulator, and low segment voltage VSL having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VCREL—relax and VCHOLD_L—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

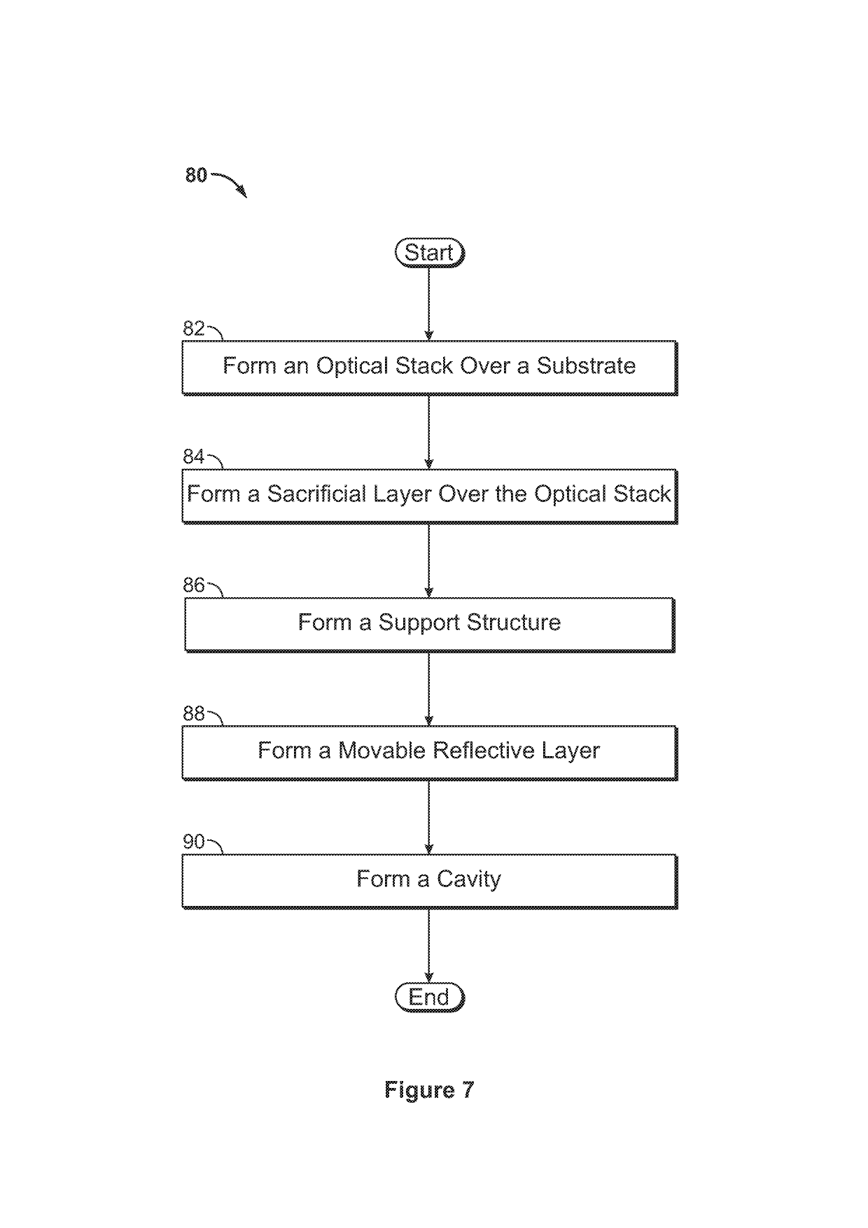

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO2). In some implementations, the support layer 14b can be a stack of layers, such as, for example, a SiO2/SiON/SiO2 tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF4) and/or oxygen (O2) for the MoCr and SiO2 layers and chlorine (Cl2) and/or boron trichloride (BCl3) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

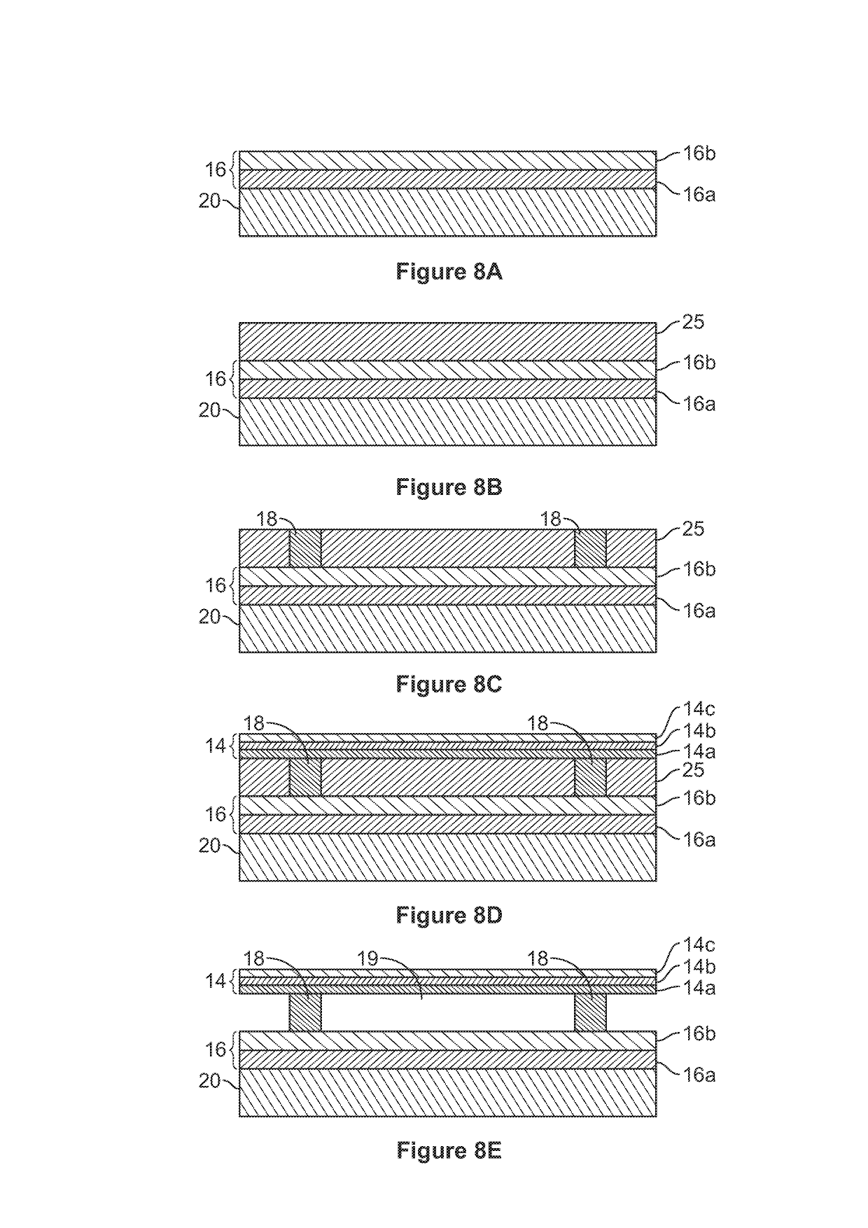

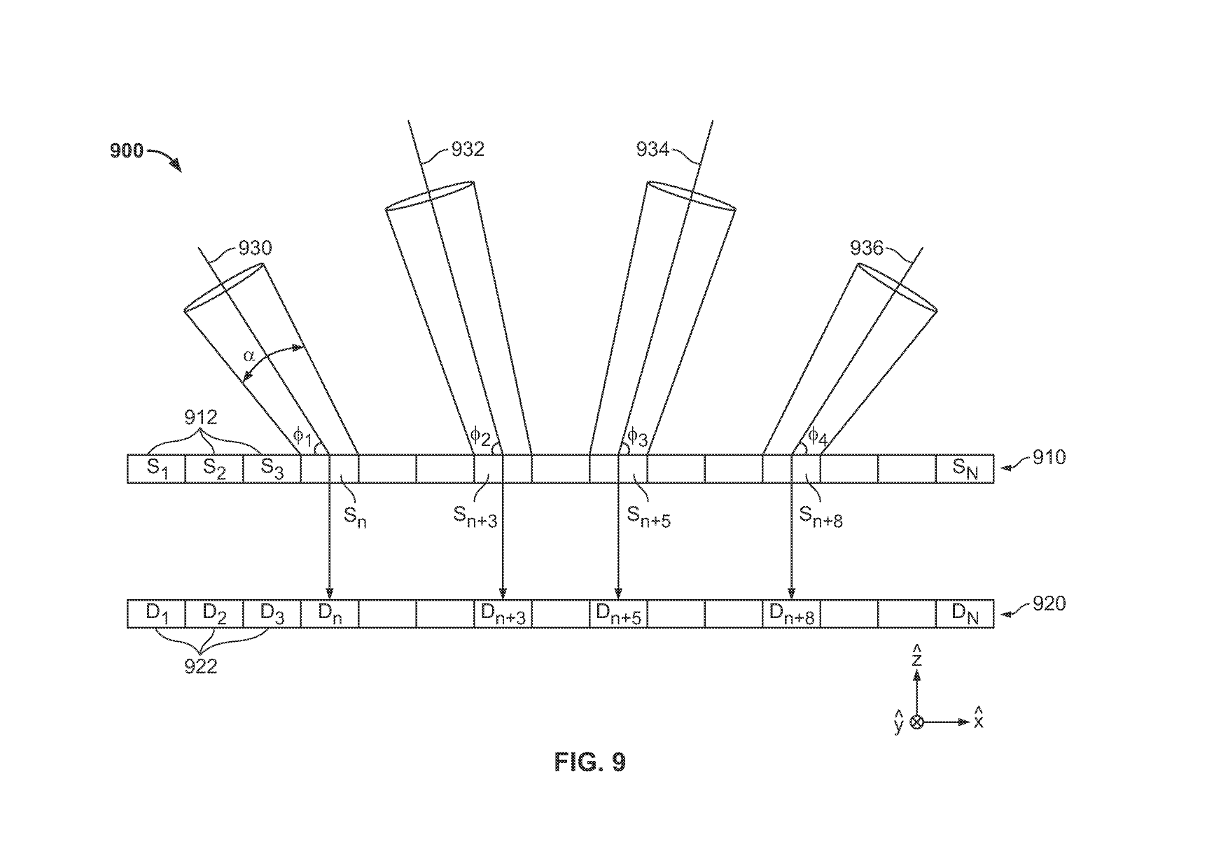

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF2)—etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF2 for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As previously mentioned, the angular distribution of ambient light that is incident upon a reflective interferometric modulator display can influence various performance factors of the display, such as view angle, color, and/or brightness. Since the ambient light distribution can vary dramatically in different viewing conditions (e.g., from Lambertian-like to directed), it would be advantageous to have the capability to measure the ambient light direction distribution. Such measurements could then be provided to a controller that adjusts various parameters of the display in response to the detected ambient lighting conditions. For example, artificial illumination levels (which may be associated with a particular voltage or current flow level), primary color light levels (e.g., red, green, blue light levels), and the emitted light diffuser level and/or angular emission cone of the display can be adjusted by the controller in response to the detected lighting conditions. Such measurements could possibly be made with a conoscope. A conoscope is a device that measures the angular distribution of light. For example, a conoscope may provide measurements of the intensity of light that is incident upon the device from each of several different directions. Conoscope measurements are useful in many applications. However, some conoscopes use complicated imaging optics and tend to be relatively expensive. Thus, it would be advantageous if angular light distribution measurements could be provided with a simpler, less-expensive device.

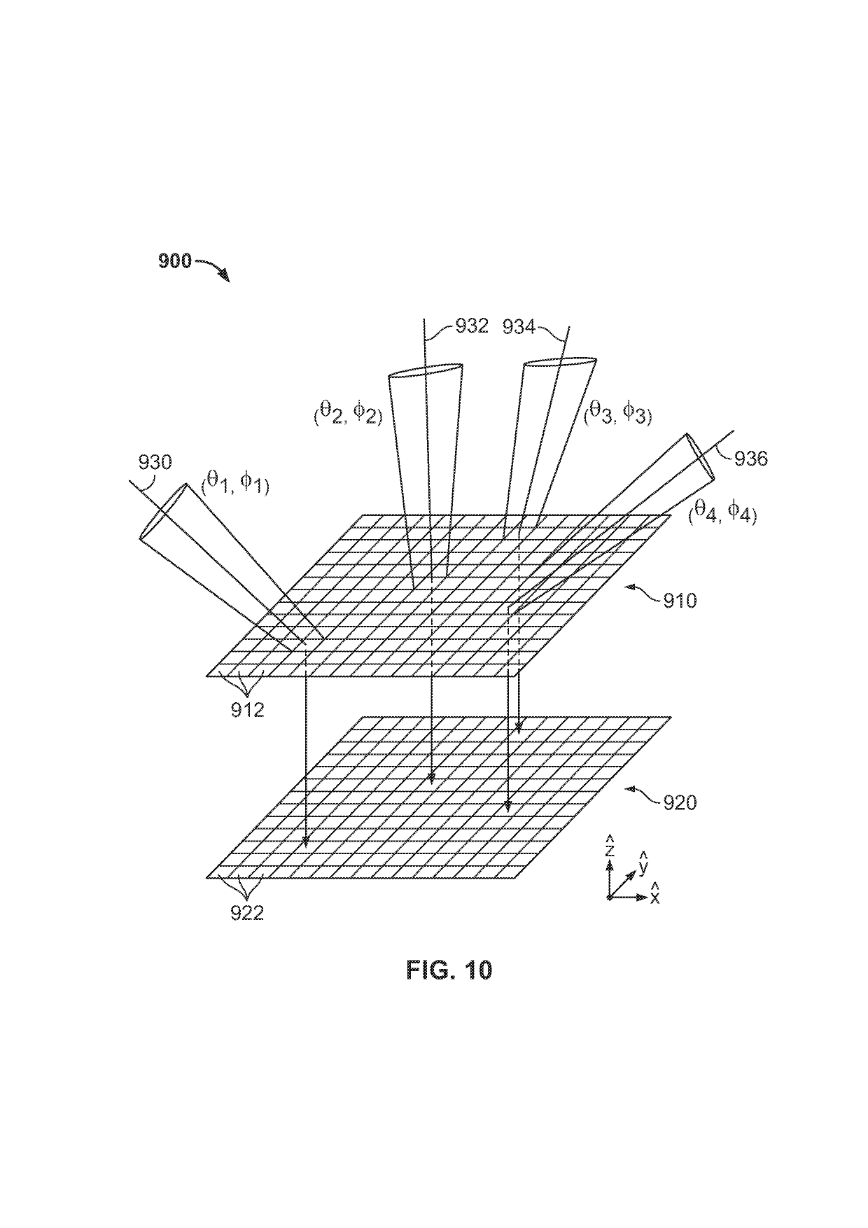

FIG. 9 is a cross-sectional schematic illustration of an example of a device 900 for measuring the angular distribution of incident light. As discussed further herein, the light direction distribution sensor device 900 includes a light steering layer 910 that is designed to steer light from different incident angles toward associated locations on a light detector 920. The detector 920 can then provide one or more signals that are indicative of the amount of light that is incident upon the sensor device 900 from different incident angles.

In some implementations, the light detector 920 includes an array of light detecting elements 922, such as detector pixels D₁, D₂, D₃ . . . D_{N}, that are arranged, for example, in a plane that is parallel to the x-y plane of the illustrated coordinate axes. The light detector 920 can be, for example, a charge coupled device (CCD) detector, a complementary metal oxide semiconductor (CMOS) detector, etc. Each light detecting element 922 receives light from the light steering layer 910 and outputs a signal that is indicative of, for example, the intensity of light that is incident upon the light detecting element. These signals from the detecting elements 922 can be sent to a processor via a communication channel, such as, for example, one or more electrical buses, wires, circuit board traces, wireless links, etc.

In some implementations, the light steering layer 910 includes an array of light steering elements 912, such as light steering elements S₁, S₂, S₃ . . . S_{N}, that are arranged, for example, in a plane that is parallel to the plane in which the light detector 920 is located but linearly displaced from it in the z-direction. Each light steering element 912 in the light steering layer 920 may be designed to steer light from a specific incident angle toward a specific light detecting element 922 in the detector 920. As a result, each light detecting element 922 can provide a signal indicative of the amount of light that is incident upon the light direction distribution sensor device 900 from the associated incident angle.

In some implementations, the light steering layer 910 includes a pixilated holographic film. Each pixel in the pixilated holographic film may be a light steering element 912, and different light steering elements 912 can be separately configured to steer light from different incident directions toward one or more associated light detecting elements 922. In other implementations, the light steering layer 910 can be a direction turning film such as those available from Luminit Co. (Torrance, Calif.). In such implementations, the direction turning film can have an array of prismatic structures that change the respective directions of propagation of incoming light beams toward associated light detecting elements 922.

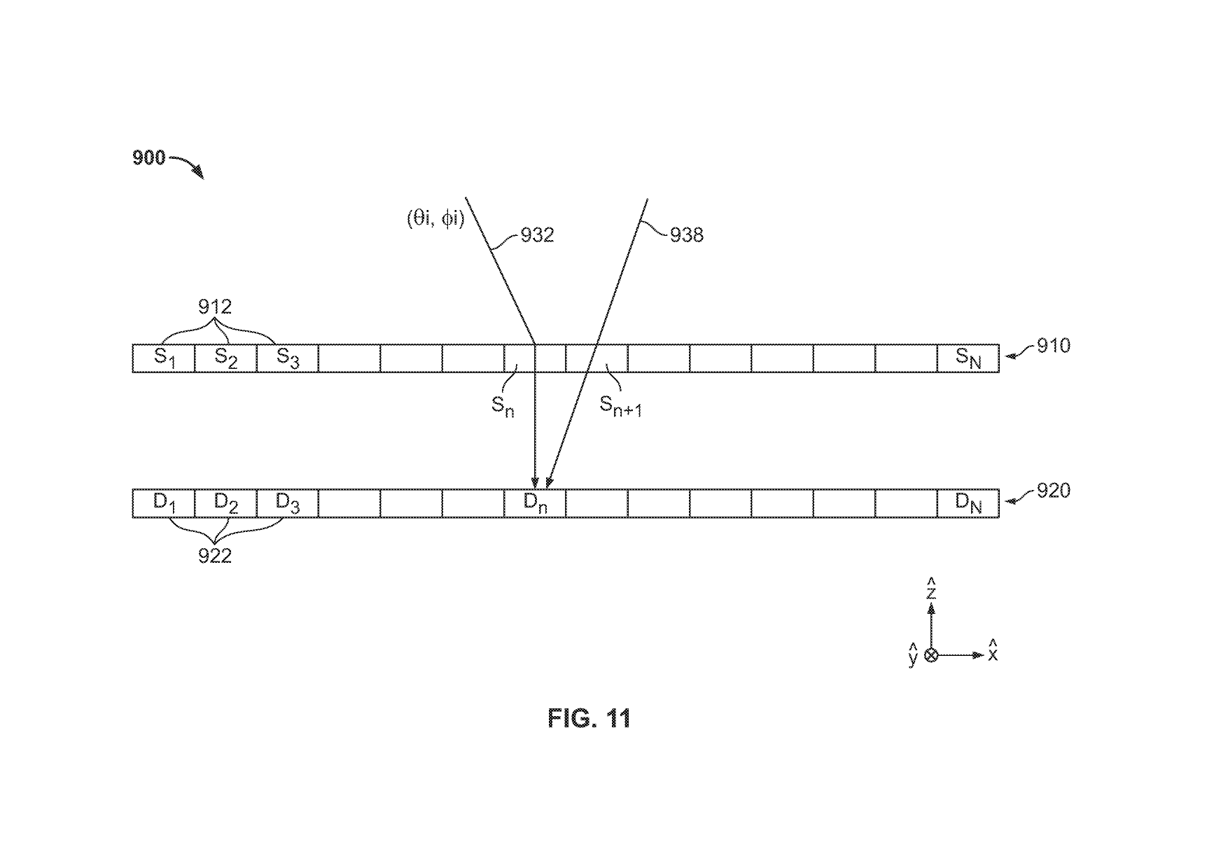

Regardless of the specific type of light steering layer 910, each of the light steering elements 912 can be designed to steer light that is incident on the light direction distribution sensor device 900 at a particular azimuth angle, θ, and a particular elevation angle, φ, towards an associated detector element 922 (see, e.g., the illustration of these angles described with reference to FIG. 10). Moreover, each light steering element 912 may do so without substantially steering incident light beams from other directions toward that particular light steering element's associated light detecting element 922. In some implementations, each light steering element 912 is located at a position (xᵢ, yⱼ) with respect to the illustrated coordinate axes, and each light detecting element 922 is located at a position (xₖ, yₗ). The subscripts i and k are indices that each reference an arbitrary location in the x-direction that is indicated by the coordinate axes in the figures, while the subscripts j and l each reference an arbitrary location in the y-direction. Taken together, the indices i and j, and k and l, address each light steering element 912 and each light detecting element 922, respectively. The light steering elements 912 can be designed and arranged such that each sampled incident angle (θₘ, φₙ) is mapped to an associated light steering element 912 located at (xᵢ, yⱼ). The subscript m is an index that references an arbitrary azimuth angle of incidence, and the subscript n is an index that references an arbitrary elevation angle of incidence. Taken together, the indices m and n address each sampled angle of incidence for which the angular distribution of light is being measured in a particular application. Similarly, each light steering element 912 located at (xᵢ, yⱼ) can be mapped to a light detecting element 922 located at (xₖ, yₗ). In this way, a light steering element located at (xᵢ, yⱼ) can be designed with, for example, diffractive, refractive, holographic, prismatic structures, combinations of the same and the like that are designed to steer a ray of light that is incident from an angle (θₘ, φₙ) toward a light detecting element 922 located at (xₖ, yₗ). Any of a variety of mappings between (θₘ, φₙ) and (xᵢ, yⱼ), and between (xᵢ, yⱼ) and (xₖ, yₗ), can be used. In some implementations, the mappings between (θₘ, φₙ) and (xᵢ, yⱼ), and between (xᵢ, yⱼ) and (xₖ, yₗ), are one-to-one, though this need not necessarily be the case. For example, the light steering layer 910 could also be designed to create a one-to-many mapping between each resolved direction of incidence (θₘ, φₙ) and multiple light detecting elements 922.

In the example shown in FIG. 9, steering elements Sₙ, Sₙ₊₃, Sₙ₊₅, and Sₙ₊₈ are respectively designed and configured to steer light that is incident at (θ₁, φ₁), (θ₂, φ₂), (θ₃, φ₃), and (θ₄, φ₄) (represented in FIG. 9 as light cones of angular width α centered about light rays 930, 932, 934, and 936, respectively) toward associated detector pixels Dₙ, Dₙ₊₃, Dₙ₊₅, and Dₙ₊₈. In some implementations, each light steering element 912 is designed to steer light from an associated incident direction (θₘ, φₙ) normally in the z-direction toward a light detecting element 922 located directly below it, as is illustrated in FIG. 9, though this is not required. In other implementations, a detector pixel 922 need not be located directly below its associated light steering element 912.

In addition, the light direction distribution sensor device 900 can include a wavelength-selective filter (not shown) to filter the light (e.g., light rays 930, 932, 934, and 936) before it is incident upon the light steering layer 910. The wavelength-selective filter can be, for example, a layer located above the light steering layer 910. The wavelength-selective filter can be included if, for example, the properties of the light steering layer 910 are wavelength dependent. For example, in the case where the light steering layer 910 includes a pixilated holographic film, the direction to which each of the pixels steers incident light may be dependent upon the wavelength of the light. Thus, the wavelength-selective filter may be used to ensure that ambient light at a particular operating wavelength arrives at the pixelated holographic film. The operating wavelength could be any representative wavelength, such as, for example, green light at about 550 nm, which is a wavelength to which the human eye is relatively more sensitive than other wavelengths.

FIG. 10 is a perspective view of the light direction distribution sensor device 900 illustrated in FIG. 9. FIG. 10 illustrates the light detector 920, which includes the array of light detecting elements 922. FIG. 10 also illustrates the light steering layer 910, which includes the array of light steering elements 912. Whereas the cross-sectional view in FIG. 9 only illustrates how the light steering layer 910 turns cones of light (e.g., those centered on light rays 930, 932, 934, and 936) that are incident at different elevation angles φ₁, φ₂, φ₃, and φ₄, respectively, toward associated light detecting elements 922, FIG. 10 illustrates that the cones of light may also be incident at different azimuth angles θ₁, θ₂, θ₃, and θ₄, respectively. FIG. 10 also illustrates an example mapping between various incident angles (θₘ, φₙ) and various light steering elements located at (xᵢ, yⱼ), as well as an example mapping between various light steering elements 912 located at (xᵢ, yⱼ) and light detecting elements 922 located at (xₖ, yₗ). While the light steering elements 912 and the light detecting elements 922 are illustrated as being laid out in a Cartesian grid, they can also be laid out in other types of grids, for example, rings/annuli according to a polar coordinate-based grid.

The size and number of light steering elements 912 in the light steering layer 910 can be determined, for example, based on the desired angular resolution of the light direction distribution sensor device 900. For example, in some implementations, the number of light steering elements 912 used to substantially equally sample the 2π steradians in a hemisphere centered over the light direction distribution sensor device 900 can be calculated from the following mathematical formula:

$$N = \frac{2}{{tan}^{2} ( \frac{α}{2} )}$$

where N is equal to the number of light steering elements used to sample a hemisphere divided equally into light cones with apex angle α.

The following table summarizes the number of light steering elements 912 used for different angular resolutions in various implementations.

| Cone Apex Angle (α) | Number of Light Steering Elements (N) |
|---|---|
| 1° | 26,261 (e.g., 162 × 162 array) |
| 2° | 6,564 (e.g., 81 × 81 array) |
| 5° | 1,049 (e.g., 32 × 32 array) |
| 7° | 535 (e.g., 23 × 23 array) |
| 10° | 261 (e.g., 16 × 16 array) |
| 15° | 115 (e.g., 11 × 11 array) |
| 20° | 64 (e.g., 8 × 8 array) |
| 30° | 28 (e.g., 5 × 5 array) |

The size of the light steering layer 910 can be calculated based on the estimates in the foregoing chart. For example, if 1° angular resolution is desired, and if the size of each light steering element 912 is 100 μm per side, then the size of the light steering layer 910 would be at least approximately 0.6″×0.6″. Alternatively, if each light steering element 912 is 1 mm per side, then the size of the light steering layer 910 would be at least approximately 6″×6″. The specific angular resolution, and accompanying light steering array sizes, can be selected based on the requirements of a given application.

In various implementations, the array of light detecting elements 922 and/or the array of light steering elements 912 can be one-dimensional arrays or two-dimensional arrays. In either case, the sensor device 900 can be used to measure the angular distribution of light incident from directions along a one or more meridians or ranges of solid angles above the light detector 920. The range of solid angles can be, for example, up to a full hemisphere (e.g., up to about 2π steradians), or only a portion thereof. For example, in some implementations, the range of solid angles (measured from vertical) can be about +/−30 degrees, about +/−45 degrees, about +/−60 degrees, about 60-90 degrees, or some other range of angles. In some implementations, the light steering elements 912 are designed to sample uniformly spaced incident angles in both azimuth and elevation angles, though this is not required, as certain ranges of incident angles could be sampled with greater or lesser resolution than others.

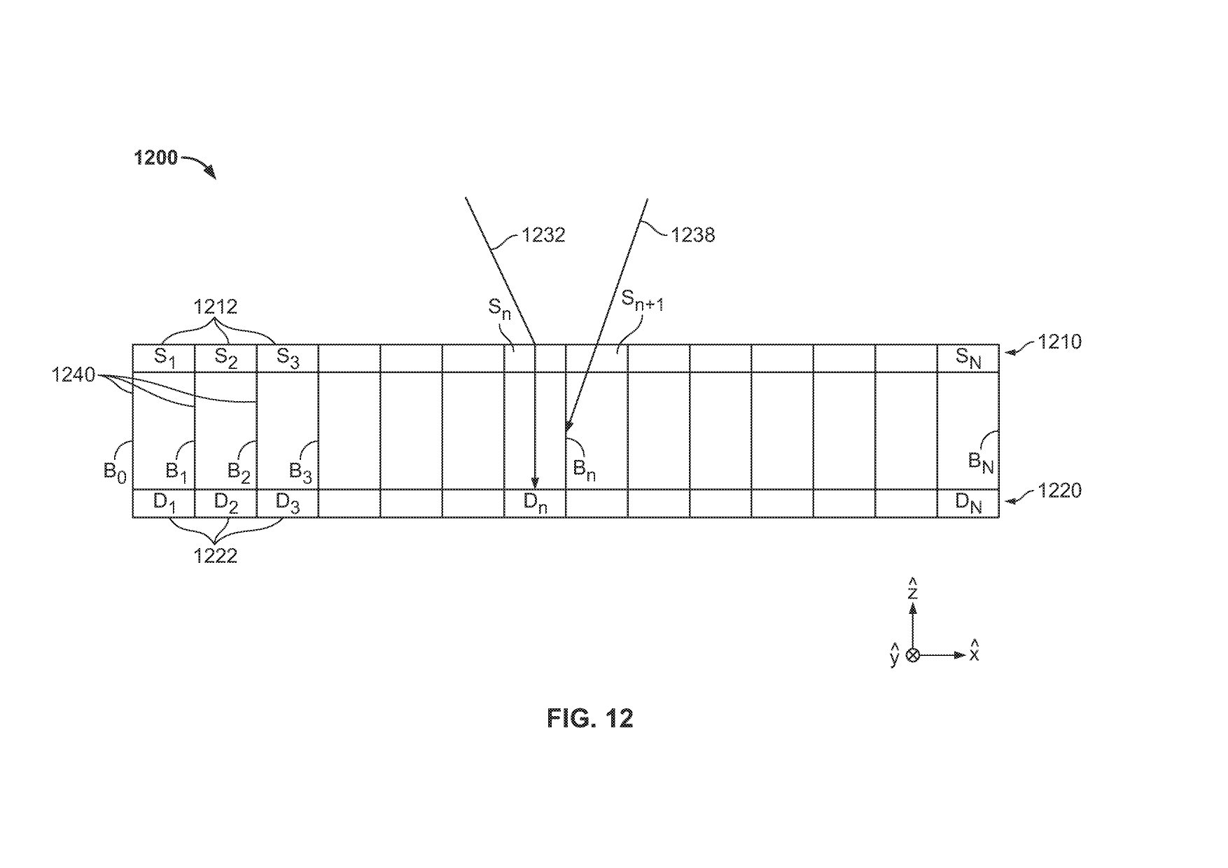

FIG. 11 is a cross-sectional schematic illustration that shows how crosstalk may occur in light angular distribution measurements taken by some implementations of the device 900 illustrated in FIG. 9. FIG. 11 shows the light detector 920 and the light steering layer 910. It also shows a light ray 932 that is incident on the light steering layer 910 at an angle (θᵢ, φᵢ) and that is turned vertically by a light steering element Sₙ toward an associated detector element Dₙ. Another light ray 938 is incident upon a neighboring light steering element Sₙ₊₁ from a different direction. In this case, if the light steering element Sₙ₊₁ is not designed to steer light rays that are incident from the direction at which the light ray 938 is incident, then the light ray 938 may be transmitted by the light steering element Sₙ₊₁ without being substantially steered, or steered in an unintended direction, toward a detector element that does not correspond to Sₙ₊₁. This phenomenon can occur for certain types of light steering elements which may only have the desired steering effect on light at a particular incident angle for which each steering element is designed. In the case illustrated in FIG. 11, light steering element Sₙ₊₁ is not designed to steer light that is incident on the light direction distribution sensor device 900 at the angle from which light ray 938 approaches the light steering layer 910. As a result, the light ray 938 may be transmitted by the light steering element Sₙ₊₁ toward non-associated detector element Dₙ. This illustrates how it may be possible for light from different incident angles to arrive at the same detector element 922, thus resulting in crosstalk in some implementations.

As illustrated in FIG. 11, the light ray 938 passes through the light steering element Sₙ₊₁ without being deviated from its direction of propagation and then is incident upon light detecting element Dₙ. Thus, optical crosstalk has occurred in this example because light detecting element Dₙ is actually intended to receive light that is incident upon the light direction distribution sensor device 900 from the direction at which light ray 932 is incident, and which is steered to it by its associated light steering element Sₙ. Since light ray 938 is also incident on light detecting element Dₙ, the signal outputted by light detecting element Dₙ becomes corrupted because it is unknown how much of the signal was contributed by light rays that are incident from the direction of light ray 932 versus how much of the signal was contributed by light rays that are incident from the direction of light ray 938. In this way, the ability of the light direction distribution sensor device 900 to resolve how much light is incident from each direction may be reduced. To counteract this phenomenon, some implementations of the light direction distribution sensor device 900 may include elements for reducing the amount of crosstalk between light detecting elements.

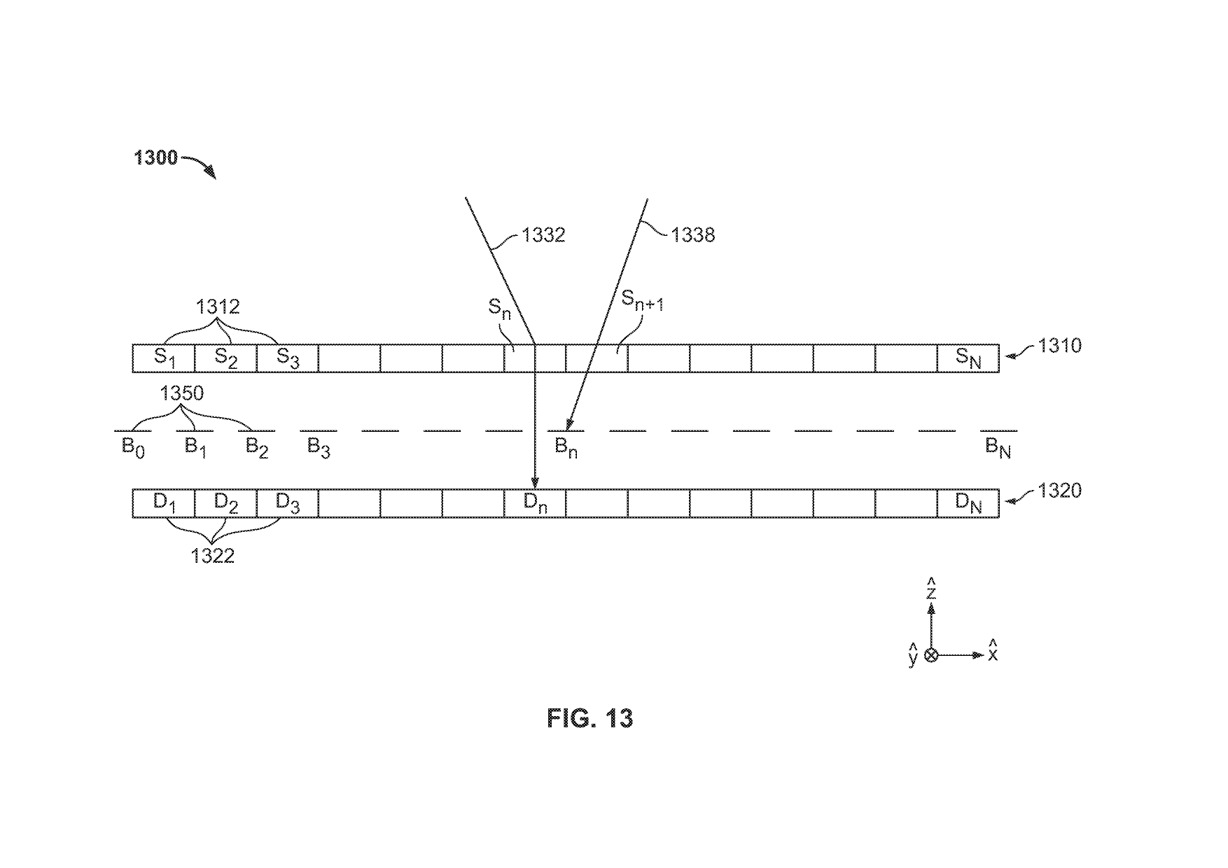

FIG. 12 is a cross-sectional schematic illustration of an example device 1200 for measuring the angular distribution of incident light with reduced susceptibility to crosstalk. The light direction distribution sensor device 1200 includes a light steering layer 1210, which includes light steering elements 1212. The sensor device 1200 also includes a light detector 1220, which includes light detecting elements 1222. The light steering layer 1210 and the light detector 1220 may be similar to those described elsewhere herein.

In addition, the light direction distribution sensor device 1200 includes a number of light baffles 1240. The light baffles 1240 may be designed and arranged so as to reduce or eliminate the amount of light that arrives at each detector element 1222 from non-associated light steering elements 1212. In FIG. 12, the light baffles 1240 include walls that extend between each light steering element 1212 and at least one associated detector element 1222. For example, the light baffles B₀, B₁, B₂, B₃ . . . B_{N} extend longitudinally between S₁, S₂, S₃ . . . S_{N} and D₁, D₂, D₃ . . . D_{N}, respectively. More specifically, light baffles B₀ and B₁ extend between the perimeter of S₁ and the perimeter of D₁ to create a walled optical channel therebetween. Similarly, light baffles B₁ and B₂ extend between S₂ and D₂ at their perimeters to create a walled optical channel therebetween, and so on. It should be understood that, if seen in a perspective view, the light baffles 1240 could form a honeycomb-type structure between the light steering layer 1210 and the light detector 1220. While the vertical light baffles 1240 in FIG. 12 extend the entire distance between the light steering layer 1210 and the light detector 1220, this need not necessarily be the case in some other implementations. In addition, the light baffles 1240 could be made up of multiple segments rather than continuous walls. In some implementations, the light baffles 1240 are made of an absorptive material so as to attenuate or eliminate errant light rays that strike the light baffles 1240.

FIG. 12 shows a light ray 1232 that is incident upon light steering element Sₙ, and which is steered by Sₙ to its associated detector element Dₙ. Another light ray 1238 is incident upon a neighboring light steering element Sₙ₊₁. As discussed with respect to FIG. 11, if Sₙ₊₁ is not designed to steer light rays that are incident at the angle at which light ray 1238 is incident, then light ray 1238 may be transmitted from Sₙ₊₁ toward a non-associated detector element (e.g., Dₙ). In the implementation illustrated in FIG. 11, this situation could result in optical crosstalk at detector element Dₙ. However, in the implementation illustrated in FIG. 12, the presence of light baffle Bₙ prevents the light ray 1238 from reaching detector element Dₙ (e.g., the light ray 1238 may be absorbed upon striking the light baffle Bₙ), thus reducing crosstalk at Dₙ. In this way, the light baffles 1240 help to reduce the amount of light from a given incident angle that arrives at light detecting elements that are intended to receive light from other incident angles. While the light baffles 1240 shown in FIG. 12 allow vertical light rays to pass while blocking non-vertical rays, in other implementations, the light baffles could be designed to provide optical channels for non-vertical rays (depending upon, for example, the mapping between light steering elements 1212 and light detecting elements 1222).

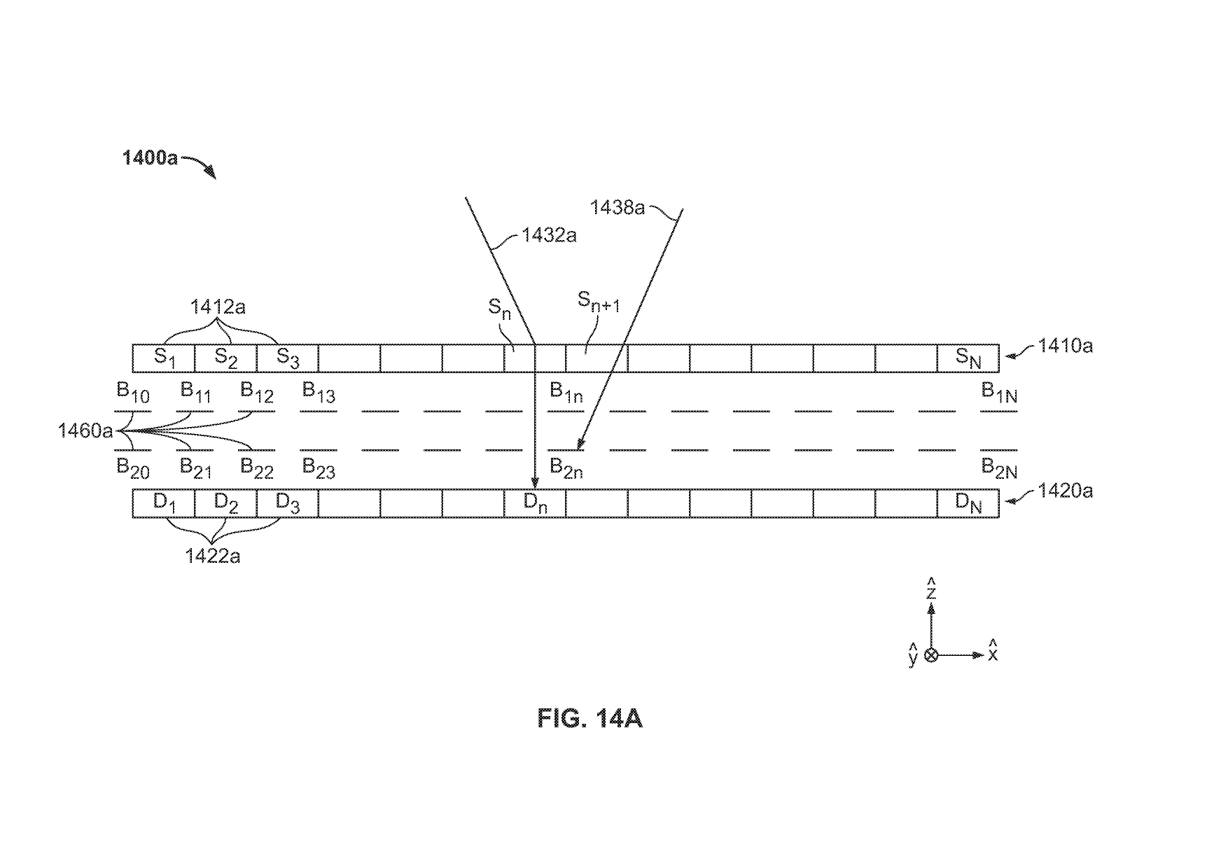

FIG. 13 is a cross-sectional schematic illustration of another example device 1300 for measuring the angular distribution of incident light with reduced susceptibility to crosstalk. The light direction distribution sensor device 1300 includes a light steering layer 1310, which includes light steering elements 1312. The sensor device 1300 also includes a light detector 1320, which includes detector elements 1322. The light steering layer 1310 and the light detector 1320 may be similar to those described elsewhere herein.

Similarly to the sensor device 1200 illustrated in FIG. 12, the sensor device 1300 in FIG. 13 includes a number of light baffles 1350. In this implementation, the light baffles 1350 include a number of horizontal wall segments B₀, B₁, B₂, B₃ . . . B_{N} that are located between the light steering layer 1310 and the light detector 1320. The horizontal wall segments B₀, B₁, B₂, B₃ . . . B_{N} could be registered with the boundaries between adjacent light steering elements 1312 and/or the boundaries between adjacent light detecting elements 1322. In some implementations, the light baffles 1350 could be formed from an absorptive material with holes formed in the absorptive material between the wall segments B₀, B₁, B₂, B₃ . . . B_{N}. Alternatively, the light baffles 1350 could be formed as, for example, opaque markings on an optically transmissive layer of material (e.g., using thin film techniques). In either case, optically transmissive portions are located along the optical paths between each light steering element 1312 and its associated light detecting element 1322. However, optically absorptive portions are provided at locations other than the intended optical path between each light steering element 1312 and its associated light detecting element 1322 so as to prevent errant light from reaching the light detecting elements 1322 and causing crosstalk.

As illustrated in FIG. 13, the light baffles 1350 allow generally vertical light rays (e.g., light rays that have been steered vertical by the light steering layer 1310) to pass between associated elements of the light steering layer 1310 and the light detector 1320. Some non-vertical rays are blocked by the light baffles 1350. For example, light baffle Bₙ prevents light ray 1338 from being transmitted by light steering element Sₙ₊₁ to non-associated detector element Dₙ (e.g., because Sₙ₊₁ may be designed to steer light rays from a direction other than the one from which light ray 1338 approaches and, therefore, may allow light ray 1338 to pass to an unintended light detecting element, as discussed herein). Meanwhile, the light baffles 1350 allow light ray 1332 to pass from light steering element Sₙ to its associated detector element Dₙ.

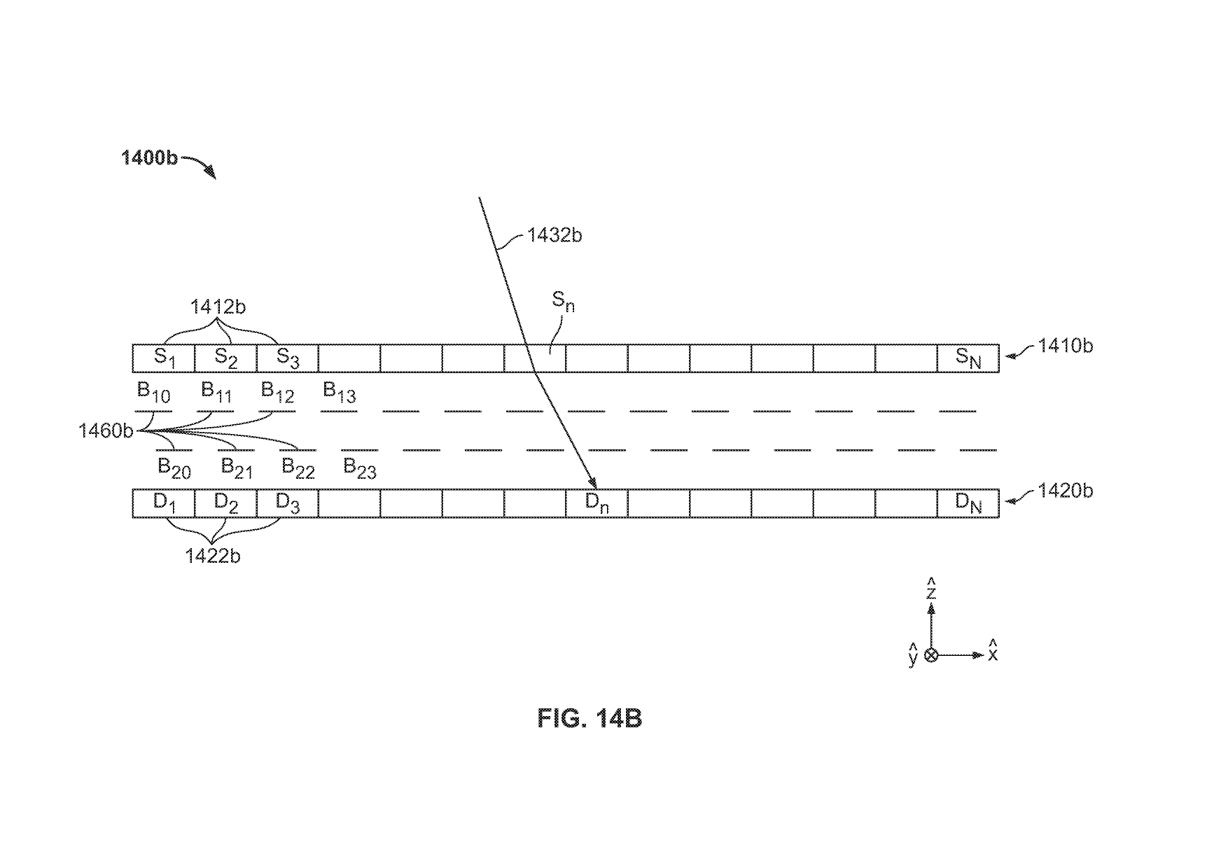

FIG. 14A is a cross-sectional schematic illustration of yet another example device 1400 for measuring the angular distribution of incident light with reduced susceptibility to crosstalk. The light direction distribution sensor device 1400a includes a light steering layer 1410a, which includes light steering elements 1412a. The sensor device 1400a also includes a light detector 1420a, which includes light detecting elements 1422a. The light steering layer 1410a and the light detector 1420b may be similar to those described elsewhere herein.

The sensor device 1400a also includes a number of light baffles 1460a. Similar to the light baffles shown in FIG. 13, the light baffles 1460a in FIG. 14A are a number of horizontal segments. However, in FIG. 14A, the light baffles are formed in two separate horizontal planes between the light steering layer 1410a and the light detector 1420a. The light baffles B₁₀, B₁₁, B₁₂, B₁₃, and B₁ₙ, are formed in a first plane, while the light baffles B₂₀/B₂₁, B₂₂, B₂₃, and B₂ₙ are formed in a second plane that is displaced from the first plane in the z-direction. In the foregoing baffle subscripts, the first digit represents the row in which the baffle is located, while the remaining digit(s) represent a location or column in that row. As illustrated in FIG. 14A, the horizontal segments B₁₀, B₁₁, B₁₂, B₁₃, and B₁ₙ can be registered with the horizontal segments B₂₀, B₂₁, B₂₂, B₂₃, and B₂ₙ, as well as the boundaries between adjacent light steering elements 1412a and/or the boundaries between adjacent light detecting elements 1422a. In some implementations, the light baffles 1460a can be formed from two layers of an absorptive material with holes formed in the absorptive material between the wall segments. Alternatively, the light baffles 1460a could be formed as, for example, opaque markings on two spaced apart layers of an optically transmissive material, or as opaque markings on opposite sides of a single layer of an optically transmissive material. In some other implementations, more than two rows of baffles could also be used such as, three, four, five, or more rows.

As illustrated in FIG. 14A, the light baffles 1460a allow generally vertical light rays (e.g., light rays that have been steered vertical by the light steering layer 1410a) to pass between associated elements of the light steering layer 1410a and the light detector 1420a. Meanwhile, some non-vertical rays are blocked by the light baffles 1460a. For example, light baffle B₂ₙ prevents light ray 1438a from being transmitted by light steering element Sₙ₊₁ to non-associated detector element Dₙ. Specifically, FIG. 14A shows how the second row of light baffles may block some light rays that may not have been blocked by a single row of baffles, since B₂ₙ blocks the light ray 1438a that passed by B₁ₙ. The light baffles 1460a do, however, allow light ray 1432a to pass from light steering element Sₙ to its associated detector element Dₙ. While the light baffles 1460a shown in FIG. 14A allow vertical light rays to pass while blocking non-vertical rays, in other implementations, the light baffles 1460a could be designed to provide optical channels for non-vertical rays (depending upon, for example, the mapping between light steering elements and light detecting elements). For example, if the horizontal segments B₁₀, B₁₁, B₁₂, B₁₃, and B₁ₙ were laterally offset from the horizontal segments B₂₀, B₂₁, B₂₂, B₂₃, and B₂ₙ, then non-vertical optical channels could be formed, as illustrated in FIG. 14B.

FIG. 14B is a cross-sectional schematic illustration of another example device 1400b for measuring the angular distribution of incident light with reduced susceptibility to crosstalk. The light direction distribution sensor device 1400b includes a light steering layer 1410b, which includes light steering elements 1412b. The sensor device 1400b also includes a light detector 1420b, which includes light detecting elements 1422b. The light steering layer 1410b and the light detector 1420b may be similar to those described elsewhere herein.

The sensor device 1400b also includes a number of light baffles 1460b. The light baffles 1460b are similar to the light baffles 1460a shown in FIG. 14A except that they are arranged to allow non-vertically steered light rays to pass between the light steering layer 1410b and the light detector 1420b. The light baffles B₁₀, B₁₁, B₁₂, B₁₃, and B₁ₙ are formed in a first row, while the light baffles B₂₀, B₂₁, B₂₂, B₂₃, and B₂ₙ are formed in a second row that is displaced from the first row in the z-direction. As illustrated in FIG. 14A, the horizontal segments B₁₀, B₁₁, B₁₂, B₁₃, and B₁ₙ can be offset with respect to the horizontal segments B₂₀, B₂₁, B₂₂, B₂₃, and B₂ₙ. This offset creates non-vertical optical channels from light steering elements 1412b to the respective associated light detecting elements 1422b. For example, the light ray 1432b is incident upon the light steering element Sₙ. The light steering element Sₙ non-vertically steers the light ray 1432b towards the associated light detecting element Dₙ, which, in this case, is laterally offset from the light steering element Sₙ. In some other implementations, more than two rows of baffles could also be used such as, three, four, five, or more rows.

Although the implementations illustrated in FIGS. 12-14 may reduce crosstalk in light angular distribution measurements, they could still allow crosstalk caused by light rays that are normally-incident upon the light steering layer (e.g., 1210, 1310, and 1410). Such normally-incident light rays may pass through a light steering element (e.g., Sₙ in FIGS. 12-14) with relatively little steering effect if that light steering element is designed to turn light that is incident at a different angle. In addition, such normally-incident light rays may not be blocked by the light baffles (e.g., the baffles 1240, 1350, and 1460), which, in the example implementations illustrated in FIGS. 12-14, are designed primarily to block non-vertical light rays (though other implementations could include light baffles for blocking vertical rays depending, for example, upon how light steering elements are mapped to light detecting elements).

This potential difficulty can be solved, at least in part, by determining a signal that is indicative of the amount of normally-incident light upon the light direction distribution sensor device (e.g., the devices 1200, 1300, and 1400). This signal can then be removed from the output signals of the light detecting elements (e.g., the light detecting elements 1222, 1322, and 1422) so as to compensate for crosstalk caused by the normally-incident light. For example, the signal that is indicative of the amount of normally-incident light upon the light direction distribution sensor device (e.g., the devices 1200, 1300, and 1400) could be determined by calculating a common component of each of the light detecting element output signals and then subtracting, or otherwise removing, the common component from each of the signals. Such a signal component that is common to each of the light detecting element output signals would likely be attributable, at least in part, to crosstalk from normally-incident light, as discussed above. The calculations and signal processing for identifying and removing the common signal component may be performed by the processor that is communicatively coupled to the light detector (e.g., the detectors 1220, 1320, and 1420).

In some implementations, the light direction distribution sensor device (e.g., the devices 1200, 1300, and 1400) is designed with at least one detector element (e.g., the light detecting elements 1222, 1322, and 1422) that receives normally-incident light. The output signal from this light detecting element could serve as a reference signal for identifying the amount of normally-incident light, and then removing crosstalk attributable to the normally-incident light from the output signals of other light detecting elements. Again, such signal processing could be performed by the processor that is communicatively coupled to the light detector (e.g., the light detectors 1220, 1320, and 1420). In some implementations, the light detecting element that is used for measuring normally-incident light could simply be located directly under a substantially non-steering portion of the light steering layer (e.g., the light steering layers 1210, 1310, and 1410). Light baffles (e.g., the light baffles 1240, 1350, and 1460) could be used to reduce or eliminate the amount of non-normally-incident light that reaches this light detecting element. Alternatively, the light detecting element that is used for measuring normally-incident light could be matched with a light steering element (e.g., the light steering elements 1212, 1312, and 1412) that steers normally-incident light at a non-vertical angle toward the light detecting element, which may be laterally offset from its associated light steering element. Once again, light baffles could be used to form an optical channel between the light detecting element that is used for measuring normally-incident light and its associated light steering element in order to reduce or eliminate crosstalk from non-normally-incident light rays.

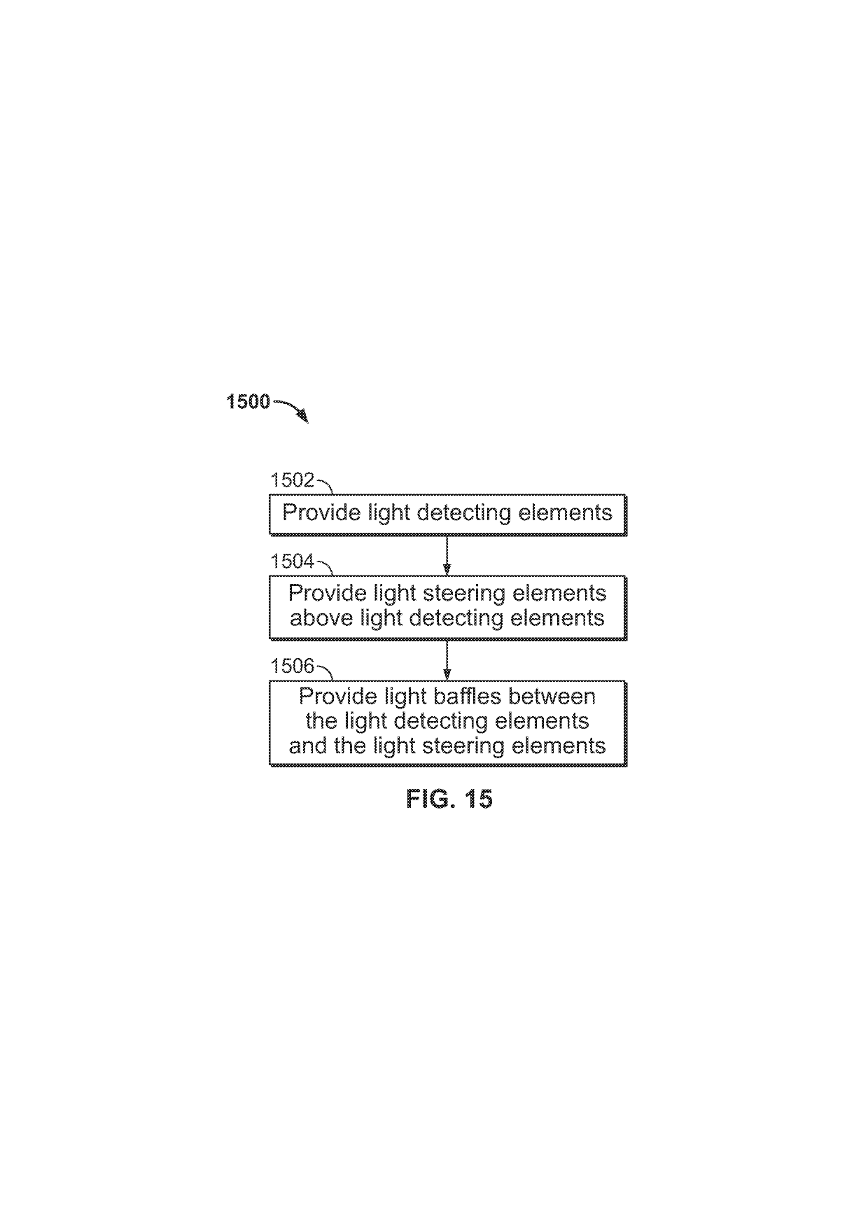

FIG. 15 is a flowchart that illustrates an example method 1500 for fabricating a device for measuring the angular distribution of incident light. The method 1500 begins with block 1502 where light detecting elements are provided. As discussed herein, the light detecting elements could include, for example, a CCD or CMOS array. The method 1500 continues at block 1504 where light steering elements are provided above the light detecting elements. As discussed herein, the light steering elements can include, for example, a pixilated holographic film or a direction turning layer. In either case, the light steering elements may include diffractive, refractive, holographic, prismatic, or other types of optical features that are designed to steer light at a particular incident angle in a particular direction. Such features can be made using, for example, known photolithography techniques. The method 1500 continues at block 1506 with providing light baffles between the light sensing elements and the light steering elements. The light baffles can be provided, for example, as vertical or horizontal walls that form optical channels (e.g., vertical or non-vertical) between light steering elements and their respective associated light detecting elements, as described herein. Once again, the light baffles can be formed using, for example, known photolithography techniques. In some implementations, the light baffles include a first layer that has transmissive portions located along optical paths from light steering elements to associated light detecting elements, and absorptive portions located elsewhere. In some implementations, multiple such layers can be formed between the light steering elements and the light detecting elements. In addition, a wavelength selective filter can be formed over the light steering elements.

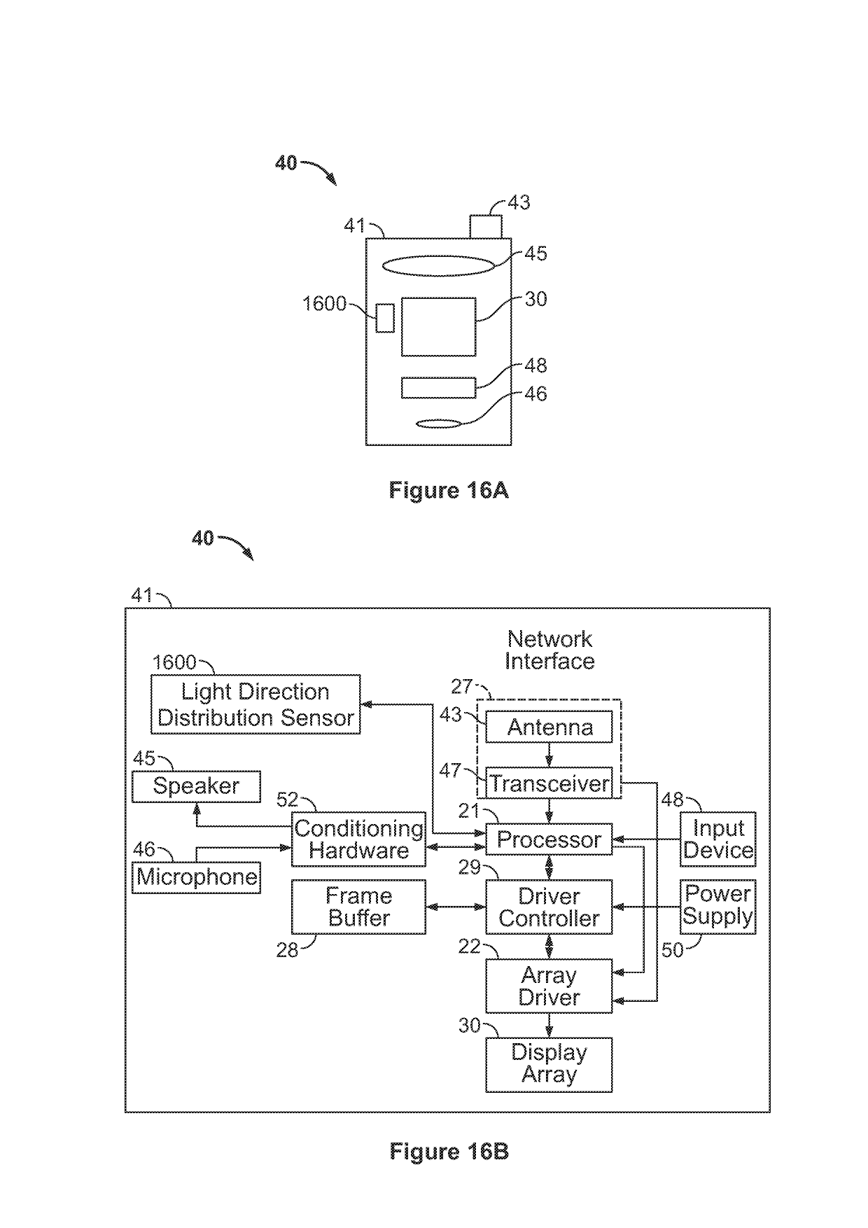

FIGS. 16A and 16B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The display device 40 can also include a light direction distribution sensor device 1600 (which can be similar to any of those described herein, e.g., devices 900, 1200, 1300, or 1400). The light direction distribution sensor device can be used to measure the amount of light that is incident upon the display device 40 from each of a variety of different directions. The light direction distribution sensor device can then output one or more measurement signals to the processor 21, which can adjust one or more parameters of the display 30 based on the detected light direction distribution.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device for measuring angular distribution of light, the device comprising:
a light detector including a plurality of light detecting elements;
a light steering layer including a plurality of light steering elements, each of the light steering elements being associated with a light detecting element and an incident direction,
wherein each of the light steering elements is configured to steer incident light from its associated incident direction toward its associated light detecting element without substantially steering incident light from other incident directions toward its associated light detecting element, and wherein different light steering elements are associated with different incident directions and different light detecting elements to allow for measurement of the angular distribution of the incident light; and
a plurality of light baffles between the plurality of light detecting elements and the plurality of light steering elements,
wherein the plurality of light baffles are configured to reduce the amount of light that passes from the light steering elements to ones of the light detecting elements other than the respective light detecting elements to which the plurality of light steering elements are configured to steer light.

2. The device of claim 1, wherein the plurality of light baffles form a plurality of optical channels between the light steering elements and the respective light detecting elements to which the light steering elements are configured to steer light.

3. The device of claim 2, wherein the plurality of light baffles include absorptive walls.

4. The device of claim 1, wherein the plurality of light baffles include a plurality of absorptive elements located between the plurality of light steering elements and the plurality of light detecting elements.

5. The device of claim 4, wherein the plurality of absorptive elements are located at positions other than optical paths from the plurality of light steering elements to the respective light detecting elements to which they are configured to steer light.

6. The device of claim 1, wherein the plurality of light baffles include a first surface having a plurality of transmissive portions, the plurality of transmissive portions being located along optical paths from the plurality of light steering elements to the respective light detecting elements to which they are configured to steer light.

7. The device of claim 6, wherein the first surface is absorptive.

8. The device of claim 6, wherein the plurality of light baffles further include a second surface, the second surface having a plurality of transmissive portions, and wherein the transmissive portions of the first and second surfaces are located along the optical paths from the plurality of light steering elements to the respective light detecting elements to which they are configured to steer light.

9. The device of claim 1, further comprising a wavelength selective filter to filter light before it is incident upon the plurality of light steering elements.

10. The device of claim 1, wherein there is a one-to-one association between the light steering elements and the light detecting elements.

11. The device of claim 1, wherein each of the light steering elements is configured to be responsive to light at a different incident angle.

12. The device of claim 1, wherein the plurality of different incident directions correspond to substantially uniformly spaced samples in elevation angle and azimuth angle with respect to the device.

13. The device of claim 1, wherein each of the light steering elements is coplanar in a first plane, and wherein the light steering elements are configured to steer the light of the plurality of different incident directions in a direction that is substantially normal to the first plane.

14. The device of claim 13, wherein each of the light detecting elements is substantially coplanar in a second plane, and wherein the second plane is substantially parallel to, and linearly displaced from, the first plane.

15. The device of claim 1, wherein the light detector includes a charge coupled device (CCD) detector.

16. The device of claim 1, wherein the light steering elements include holographic elements.

17. The device of claim 16, wherein the light steering layer includes a pixelated holographic film.

18. The device of claim 1, wherein the light steering layer includes a film having a plurality of prismatic structures disposed thereon.

19. The device of claim 1, further comprising a processor communicatively coupled to the light detecting elements, the processor being configured to determine a measure of the amount of light incident upon the device from the plurality of different incident directions based on signals from the light detecting elements.

20. The device of claim 19, wherein the processor is configured to remove a common signal from the signals from the light detecting elements, the common signal corresponding to light that is incident upon the light detecting elements without being substantially steered by the light steering elements.

21. The device of claim 20, wherein at least one of the light steering elements is configured to steer normally incident light to at least one of the light detecting elements so as to provide the common signal.

22. The device of claim 1, wherein the device is integrated with a display system having a display, the display system being configured to receive input from the device to control, at least in part, parameters of the display that are dependent upon the angular distribution of ambient light.

23. The device of claim 22, wherein the display system further includes:
a processor that is configured to communicate with said display, said processor being configured to process image data; and
a memory device that is configured to communicate with said processor.

24. The device of claim 23, wherein the display system further includes a driver circuit configured to send at least one signal to said display, and a controller configured to send at least a portion of said image data to said driver circuit.

25. The device of claim 23, wherein the display system further includes an image source module configured to send said image data to said processor.

26. The device of claim 25, wherein said image source module includes at least one of a receiver, transceiver, and transmitter.

27. The device of claim 23, wherein the display system further includes an input device configured to receive input data and to communicate said input data to said processor.

28. A device for measuring angular distribution of light, the device comprising:
means for detecting light;
means for steering light associated with the light detecting means, wherein the light steering means are configured to steer incident light with different incident directions to different associated light detecting means to allow for measurement of the angular distribution of the incident light; and
means for reducing crosstalk between the light detecting means and light steering means, wherein the crosstalk reduction means are configured to reduce the amount of light that passes from the light steering means to light detecting means other than the associated light detecting means to which the light steering means are configured to steer light.

29. The device of claim 28, where the light detecting means include a light detector having a plurality of light detecting elements, wherein the light steering means include a light steering layer having a plurality of light steering elements, and wherein the crosstalk reduction means includes a plurality of light baffles.

30. The device of claim 28, further comprising means for wavelength filtering light before it is incident upon the steering means.

31. The device of claim 28, further comprising a processor that is communicatively coupled to the light detecting means, the processor configured to determine a measure of the amount of light incident upon the device from the plurality of different incident directions based on signals from the light detecting means.

32. The device of claim 28, wherein the device is integrated with means for displaying an image, the displaying means being configured to receive input from the device to control, at least in part, parameters of the displaying means that are dependent upon the angular distribution of ambient light.

33. A method of fabricating a device for measuring angular distribution of light, the method comprising:
providing a plurality of light detecting elements;
providing a plurality of light steering elements above the plurality of light detecting elements, each of the light steering elements being associated with a light detecting element and an incident direction,
wherein each of the light steering elements is configured to steer incident light from its associated incident direction toward its associated light detecting element without substantially steering incident light from other incident directions toward its associated light detecting element, wherein different light steering elements are associated with different incident directions and different light detecting elements to allow for measurement of the angular distribution of the incident light; and
providing a plurality of light baffles between the light detecting elements and the light steering elements,
wherein the plurality of light baffles are configured to reduce the amount of light that passes from the light steering elements to ones of the light detecting elements other than the respective light detecting elements to which the plurality of light steering elements are configured to steer light.

34. The method of claim 33, wherein providing the plurality of light baffles includes providing a plurality of optical channels between the light steering elements and the respective light detecting elements to which the light steering elements are configured to steer light.

35. The method of claim 33, wherein providing the plurality of light baffles includes providing a first layer between the light detecting elements and the light steering elements, the first surface having a plurality of transmissive portions, the plurality of transmissive portions being located along optical paths from the plurality of light steering elements to the respective light detecting elements to which they are configured to steer light.

36. The method of claim 35, wherein providing the plurality of light baffles further includes providing a second surface between the light detecting elements and the light steering elements, the second surface having a plurality of transmissive portions, and wherein the transmissive portions of the first and second surfaces are located along the optical paths from the plurality of light steering elements to the respective light detecting elements to which they are configured to steer light.

37. The method of claim 33, further comprising providing a wavelength selective filter over the light steering elements to filter light before it is incident upon the plurality of light steering elements.
